(19) United States
(12) Patent Application Publication
(10) Pub. No.: US 2010/0065821 A1
(43) Pub. Date: Mar. 18, 2010

(54) Molecular quantum interference device

(76) Inventors: John Boland, Dalkey (IE); Stefano Sanvito, Dublin (IE); Zekan Qian, Beijing (CN); Rui Li, Beijing (CN); Shimin Hou, Beijing (CN)

Correspondence Address: SEED INTELLECTUAL PROPERTY LAW GROUP PLLC, 701 FIFTH AVE, SUITE 5400, SEATTLE, WA, 98104, US

(21) Appl. No.: 12/284,093

(22) Filed: Sep. 17, 2008

(51) Int. Cl. H01L 29/12; G06F 17/50

(52) U.S. Cl. 257/24; 703/14; 257/E29.069

(57) ABSTRACT

A molecular quantum interference device is provided. A method for the design of such devices is also provided, the method including modelling of device performance.

### BACKGROUND

1. Technical Field

The present specification relates to a molecular quantum interference device.

2. Description of the Related Art

Molecular electronics has been proposed for tackling the limitation of Si microelectronic device miniaturization, and therefore is a potential technology at the end of the Si roadmap. The idea concerns using molecules as active components of a device, allowing high integration density and enhanced circuit performances [1,2]. At present, most of the experimental studies are focused on the measurement of the conductance of individual molecules and these have demonstrated the applicable foreground of molecular electronics [3-9].

Challenges remain in the assembly of single-molecule devices to form complex circuits. In particular, one needs to construct interconnects whose size is comparable with that of the molecules to measure, since bulk contacts can only be used as incoherent electron source and sink as their size is significantly larger than the electrons coherence length. Moreover, most proposals involve extending conventional concepts based field effect devices that require the formation of three effective contacts to single molecules, and for which there are no actual or scalable solutions. In contrast molecular-scale interconnects can be part of a phase coherent device allowing electron wave-function manipulation.

There are therefore a number of problems that need to be addressed in terms of design and construction of molecular devices.

### BRIEF SUMMARY

These needs and others are addressed by a device in accordance with the teachings of the embodiments of the invention. Such a molecular quantum interference device comprises two molecules connected via a one-dimensional interconnect, wherein the interconnect between the molecules is gated and the applied gate voltage is controllable to control the electron phase in the interconnect.

These and other features will be better understood with reference to the exemplary arrangements which follow and which are provided to assist in an understanding of the present teaching.

### BRIEF DESCRIPTION OF THE DRAWINGS

The patent or application file contains at least one drawing executed in color. Copies of this patent or patent application publication with color drawings will be provided by the Office upon request and payment of the necessary fee.

Embodiments of the present invention will now be described with reference to the accompanying drawings in which:

FIG. 1(a) is a schematic diagram of a circuit obtained by connecting in series two single-molecule devices. Both the transmitted and reflected waves at the molecules travel in the interconnect region between them, generating quantum interference. FIGS. 1(b) and (c) show respectively the average on-site energy (electrostatic potential); and the excess charge on atoms of a single-benzene device are compared with those of the corresponding part in a two-benzene device using 16 carbon atoms as the interconnect based on the completion of fully self-consistent calculations, which demonstrates the validity of the independent-device assumption. The circles labelled with H represent the hydrogen atoms in benzene, while other circles represent carbon atoms in benzene and the interconnect.

FIG. 2(a) is a graphical illustration of transmission and reflection coefficients and FIG. 2(b) is a graphical illustration of transmission and reflection phase of the single-molecule device consisting of a benzene molecule sandwiched between C monatomic chains. The inset illustrates the HOMO and LUMO states of benzene, which make the most of the contribution to the transmission near the Fermi energy EF. Note that EF is shifted to zero and the Fermi wave vector of the carbon monatomic chain is k_{f}=π/2a₀, where a0=1.29 Å is the C—C bond length.

FIG. 3(a) shows transmission coefficients as a function of energy of the two-molecule devices using respectively 16 carbon atoms and 17 carbon atoms interconnect. The transmission coefficient of the single-molecule device is also given for comparison. EF is taken to be zero; FIG. 3(b) shows the current-voltage characteristics of these two-molecule device, compared with that of the single-molecule one; and FIG. 3(c) shows conductance at a small bias 0.1V as a function of the number of carbon atoms in the interconnect. FIG. 4(a) is a schematic diagram of a FET-like circuit; FIG. 4(b) is a graphical illustration of the shift of the energy band as a function of the applied gate voltage; FIG. 4(c) is a graphical illustration of the transmission coefficients of the two-molecule circuit with 16 carbon atoms used as the interconnect at the gate voltages of 0.0V (blue), 4.0V (red) and +4.0V (green). A clear shift of the transmission coefficient can be seen; FIG. 4(d) shows source-drain current (Isd) versus the bias voltage (Vsd) at different gate voltages; and FIG. 4(e) shows source-drain current (Isd) versus the gate voltage (Vg) for this two-molecule circuit at Vsd=0.5V.

### DETAILED DESCRIPTION

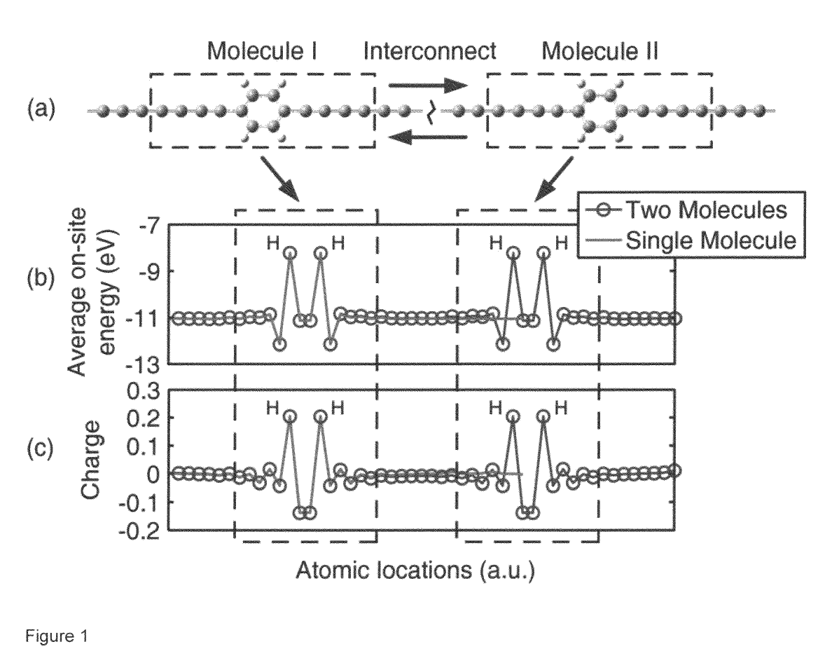

Referring to the drawings and initially in particular FIGS. 1(a) and 4(a) a device 100 comprises two single molecule devices 101 connected in series. The single molecule devices 101 comprise molecules 102 connected via a one dimensional wire interconnect 103. The molecules 102 in this case comprise benzene molecules. The interconnect 103 may comprise a monatomic chain for example, of carbons atoms. In this case, the interconnect 103 comprises a 16 or 17 carbon atom chain.

The interconnect 103 between the molecules is gated and the device 100 is configured for operation based on control of the electron phase by control of the applied gate voltage. The device 100 is thus operable on the basis of quantum mechanical interference. In particular, the transmitted and reflected waves travel in the interconnect 103 to generate quantum interference.

The size of the interconnect 103 is comparable with or on the order of that of the molecules 102. The size of the interconnect 103 is further comparable to or on the order of the phase relaxation length.

In the present molecular device 100 phase relations between the different circuit components are determined. Initially, the two molecule circuit 100 may be considered as comprising two single molecule devices 101 connected in series. The devices 101 may be considered independently.

Referring to FIG. 4(a) the device 100 comprises an FET-like device in which the interconnect is gated.

The behaviour of the device 100 as a gate voltage is applied orvaried is considered. When a positive gate voltage is applied, peaks in the transmission coefficient shift to lower energies as the voltage increases, providing an increase in conductance at Fermi Energy EF. When a negative gate voltage is applied peaks in the transmission coefficient shift to higher energies resulting in a higher zero-bias conductance. Thus the transmission co-efficient may be modulated with applied gate voltage.

Further, the I-V curve of a two molecule circuit may be controlled by gating the interconnect 103 and controlling the voltage applied. In effect circuit performance is controlled by controlling the electron phase in the interconnect 103.

With reference to the drawings, background and design considerations, structure and performance of the device are considered in further detail. A method 200 of analysing and modelling the performance of the devices 100 and 101 is provided.

Importantly, when the size of the interconnects 103 between molecules 102 is comparable to or on the order of the phase relaxation length, standard Kirchhoff's laws breakdown and the whole circuit 100 becomes a phase coherent object. This opens the possibility to use quantum mechanical interference instead of the electrostatics for operating the device. Here accurate ab initio transport calculations for describing the operation of two-terminal devices containing multiple molecular components are provided.

A widely used theoretical approach for calculating electronic transport in real systems [15,16] combines the non-equilibrium Green's function (NEGF) formalism with density functional theory (DFT) [17-20]. Typically a phase-coherent circuit 100 may be modelled by performing a self-consistent calculation for the whole device, i.e. by including in the simulation cell both the molecules and the interconnects. A limitation in this approach however is that only the transport properties of the entire device are evaluated and information on the individual phase-relations between the different components is lost.

For this reason, in order to interpret better results, here in the present method 200 a second strategy using a divide and conquer technique combined with the scattering matrix formalism (S-matrix) is adopted.

The device 100 is divided into and considered as comprising sections 101 (see FIG. 1(a)), the S-matrices of each section (with NEGF+DFT) are calculated, and finally combined in writing the S-matrix of the entire circuit. From the total S-matrix the conductance is evaluated with the Landauer-Büttiker formula [22]

$$T = {\sum }_{α β} {\vert {t}_{α β} \vert}^{2} ( {v}_{α}^{out} / {v}_{β}^{in} ) .$$

Here t is the transmission matrix, vout and vin are the velocities of the transmitted and the incident waves respectively, and the subscript runs over the different channels in the electrodes [22].

In this present method 200 the computational costs are advantageously kept at the level of those necessary to calculate a single element 101 of the circuit. And furthermore the phase relations between the different circuit components are explicitly taken into account. The method 200 assumes that the devices 101 in the circuit can be considered as independent, i.e. that the existence of one device does not affect the Hamiltonian and the charge distribution of the other. In addition, the electrodes connecting different devices are taken to be long enough to be treated electronically as infinite periodic systems. This corresponds to the standard assumption that electrons from the electrodes are injected incoherently into the device 100.

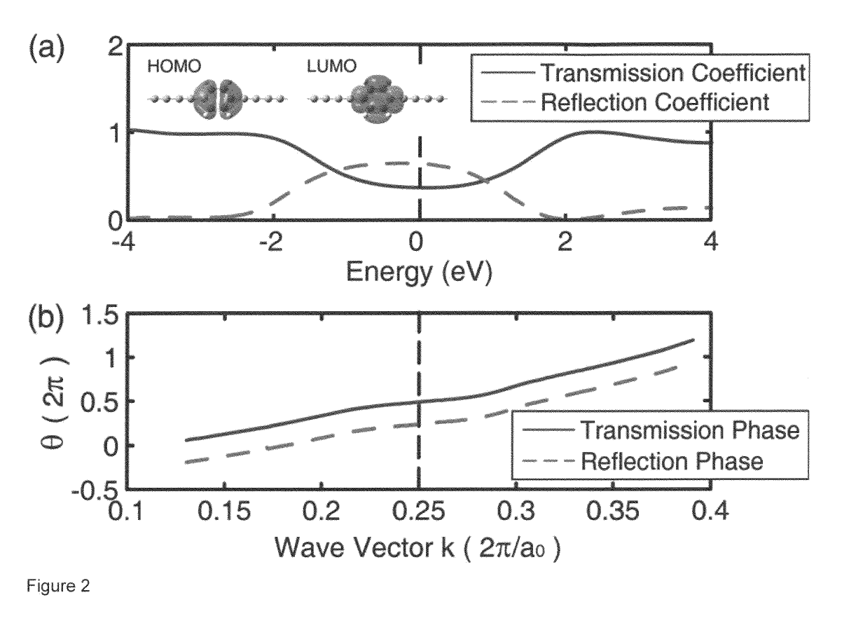

Referring to the drawings, analysis in the method 200 is thus based on a simple single-molecule device 101 formed from a benzene molecule connected to C monatomic chain electrodes. Monatomic C chains have been already reported to be one-dimensional molecular wires promising for molecular circuitry. Due to the conjugation between the benzene and the C chain this single-molecule device 101 has a high conductance near the Fermi energy, EF, with a transport channel 106 mainly formed from the highest occupied molecule orbital (HOMO) and the lowest unoccupied molecule orbital (LUMO) of the benzene. HOMO and LUMO are delocalized π bonds and also possess a large amplitude over the two C atoms connecting the benzene to the electrodes (see inset of FIG. 2(a)).

In the case of only one transport channel 106 in the electrodes, both the transmission and reflection matrices reduce to two complex numbers, with their absolute values squared corresponding respectively to the transmission and reflection coefficient (FIG. 2(a)). Their complex arguments, the transmission phase θt and reflection phase θr, account for the phase shifts of an electron when either transmitted or reflected by the molecule (see FIG. 2(b)).

Although the phases are often ignored in most two-terminal transport calculations, they are important in a multi-molecule coherent circuit 100. of the present specification.

Referring to FIG. 2(b), both θt and θr show an approximately linear behavior with the wave vector k of the incident channel. The fitted slope for the two phases, in units of the C—C distance a0=1.29 Å, is found to be around N0=4.13. Note that, as the transmission coefficients, and also the phases are determined by the molecule and the portion of the electrodes adjacent to the molecule where the potential is not that of bulk. This forms the building block for the divide and conquer scheme. Therefore part of the electrodes is always included in the self-consistent calculation of the transport coefficients [16].

Next the method comprises connecting two identical molecules 102 together via an interconnect 103 in this case a C monatomic chain (see FIG. 1(a)).

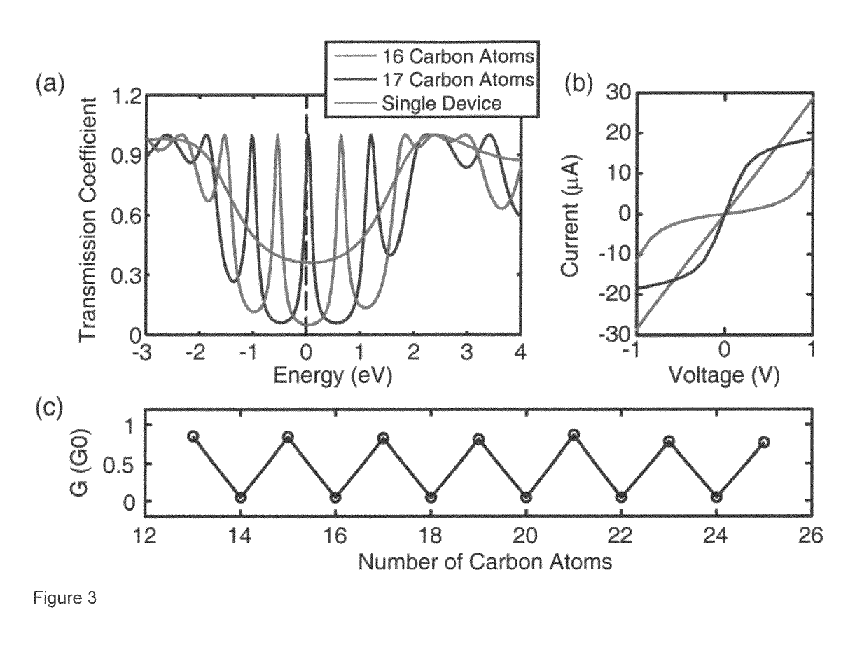

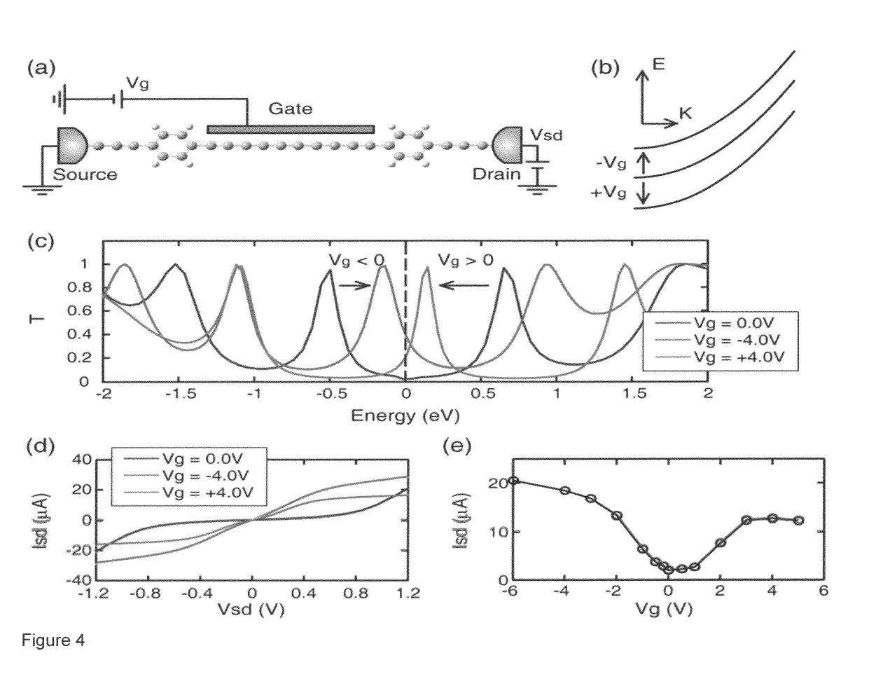

FIG. 3(a) shows the calculated transmission coefficients for two interconnects 103 of different lengths in comparison with that of a single-molecule junction. The calculations in this case have been performed with the fully self-consistent algorithm [16] and further interpreted by using the divide and conquer scheme. As expected from quantum interference, for the double-molecule junctions these are found to be an oscillating function of the energy of the incident electron and they are rather sensitive to the actual interconnect length. For instance, there is a half-period shift near EF when the length of the interconnect increases from 16 to 17 carbon atoms. The oscillations of T(EF) can then be understood directly from the S-matrix of the whole device expressed in terms of the S-matrices of the individual molecules (identical in this case). For electrodes with only one scattering channel 106, the transmission coefficient of the two-molecule device 100 follows the equation T₂=|T₁/(1−R₁ exp(2iθᵣ+2ika₀N))|², where T1 and R1 are the transmission and reflection coefficients of the single-molecule device 101 (FIG. 2(a)) and N denotes the number of unit cells in the interconnect 103. The oscillations of this phase-coherent system are determined by the exponent with the period mainly given by the band energy and the length of the interconnect:

$$Δ E = Δ k ( Δ E / Δ k ) • \frac{π}{( N + {N}_{0} ) {a}_{0}} \frac{\partial E}{\partial k} .$$

Here we have assumed a linear relation between θr and the wave vector θᵣ=ka₀N₀+C as suggested in FIG. 2(b). Note that when one adds one cell to the interconnect, i.e. when its length goes from N to N+1 carbon atoms, the phase increases by 2k_{f}a₀ΔN=π at EF, since the C monatomic chain has a half-filled band with the Fermi wave vector k_{f}=π/2a₀. Thus, the transmission coefficient displays a half-period shift near EF when the length of the interconnect increases from 16 carbon atoms to 17 carbon atoms.

As a result of the oscillatory transmission coefficient, step-like current-voltage (I-V) curves are obtained for these two-molecule circuits 100 (see FIG. 3(b)).

These are sensitive to the interconnect 103 length. For instance, if we look at the conductance calculated at 0.1 Volt, we find a clear oscillating behavior as a function of the interconnect length (see FIG. 3(c)), with conductances larger for odd-numbered interconnects than for even-numbered ones.

This phenomenon is similar to that of carbon monatomic chains sandwiched between two metal contacts as reported previously [23]. However in the case of the device 100 the scattering potential defining the quantum interference region is not defined by the contact area between the transport channel and the electrodes, but it is a part of the quantum device itself.

The oscillation in the transmission coefficient and thus the step-like I-V curves are universal properties of multi-molecule coherent devices 100.

This provides a new method for tuning the circuit 100 performance by controlling the electron phase in the interconnect 103. This is an alternative to the prior approach of controlling the position of the energy levels of the molecules.

Although in the two-molecule device 100 discussed before, the phase was controlled by the length of the interconnect 103 (FIG. 3(c)), the same phase-shift can be achieved by other means. This represents a powerful concept for designing high-sensitivity devices and sensors.

Referring to FIG. 4(a) two molecules 101 are connected using a 16-C-atom monatomic chain used as interconnect. 103. A constant voltage simulating the gate electrode is applied to these 16-carbon atoms. This effectively is equivalent to using a gate with 100% gating efficiency. It is only a simplification in the computational method and results and concepts are not changed by a more realistic gate description. Since the interconnect 102 in this situation can no longer be treated as an infinite periodic system due to the applied voltage, a fully self-consistent calculation including both the two molecules 102 and the interconnect 103 in the simulation cell [16] is performed. The transmission coefficient data is provided in FIG. 4(c).

When a positive gate voltage is applied, the peaks in the transmission coefficient shift to lower energies as the voltage increases, leading to an increase of the conductance at EF.

Similarly, the peaks in T(E) shift to higher energies for negative voltages, also resulting in a higher zero-bias conductance. This result can be easily understood by looking at the shift of the energy band of the C monatomic chain as a function of the gate voltage (see FIG. 4(b)). A positive gate voltage shifts the energy band downwards in energy.

Such an energy shift generates the peak shift in the transmission coefficient, and thus modifies the zero-bias conductance. Note also that the modulation of T(E) with the gate voltage saturates at large voltages. This is a consequence of the local charge neutrality violation as the result of the shift of the energy band. Such violation counterbalances the effects of the local gate voltage leading to a saturation of the band-shift as the voltage increases, and thus to a saturation in the T(E) modulation (FIG. 4(e)).

The present specification describes performance of phase-coherent molecular quantum interference circuits and in particular an example circuit consisting of multiple benzene molecules. Advantageously, oscillations in the transmission coefficient originating from the electron interference in the interconnect have been found. Since those are a universal feature of multi-molecule coherent devices and significantly depend on the properties of the interconnect, the present specification provides a molecular quantum interference device in which the circuit performance may be tuned by controlling the electron phase in the interconnect instead of controlling energy levels of the molecules. Furthermore, gating the interconnect may be used to effectively control the I-V curve of a two-molecule circuit, providing a new structure for FET-like devices.

The words comprises/comprising when used in this specification are to specify the presence of stated features, integers, acts, steps or components but does not preclude the presence or addition of one or more other features, integers, acts, steps, components or groups thereof.

### REFERENCE

[1] A. Nitzan, M. A. Ratner, Science 300,1384 (2003)
[2] N. J. Tao, Nature Nanotechnology 1, 173 (2006)
[3] M. A. Reed, et al., Science 278, 252 (1997)
[4] B. Xu, N. J. Tao, Science 301, 1221 (2003)
[5] L. Venkataraman, et al., Nature 442, 904 (2006)
[6] M. Elbing, Proc. Natl. Acad. Sci. USA 102, 8815 (2005)
[7] J. Chen, et al., Science 286,1550 (1999)
[8] M. A. Reed, et al., Appl. Phys. Lett. 78, 3735 (2001)
[9] B. Xu, et al., J. Am. Chem. Soc. 127, 2386 (2005)
[10] P. Qi, et al., J. Am. Chem. Soc. 126, 11774 (2004)
[11] X. Guo et al., Science 311, 356 (2006)
[12] Z. Crijen and G. Baranović, Phys. Rev. Lett. 98, 116801 (2007)
[13] Z. Qian, et al., J. Chem. Phys. 127,194710 (2007).
[14] Y. Xue, S. Datta, M. A. Ratner, Chem. Phys. 281, 151 (2002)
[15] A. R. Rocha, et al., Phys. Rev. B 73, 085414 (2006); A. R. Rocha, et al., Nature Materials 4, 335 (2005).
[16] Y. Meir and N. S. Wingreen, Phys. Rev. Lett. 68, 2512 (1992).
[17] K. S. Thygesen, Phys. Rev. B 73, 035309 (2006).
[18] P. Hohenberg and W. Kohn, Phys. Rev. 136, B864 (1964).
[19] W. Kohn and L. J. Sham, Phys. Rev. A 140,1133 (1965).
[20] M. Buttiker, et al., Phys. Rev. B. 31,6207 (1985)
[21] N. D. Lang and Ph. Avouris, Phys. Rev. Lett. 81, 3515(1998); ibid, 84, 358 (2000).

1. A molecular quantum interference device comprising two molecules connected via a one-dimensional interconnect, wherein the interconnect between the molecules is gated and an applied gate voltage is controllable to control the electron phase in the interconnect.

2. A device as claimed in claim 1 wherein the size of the interconnect is comparable with that of the molecules.

3. A device as claimed in claim 1 wherein the size of the interconnect is comparable to the phase relaxation length of charge carriers in the interconnect.

4. A device as claimed in claim 1 wherein the molecules comprise benzene molecules.

5. A device as claimed in claim 1 wherein the interconnect comprises a one dimensional wire

6. A device as claimed in claim 1 wherein the interconnect comprises a monatomic carbon chain.

7. A device as claimed in claim 1 wherein the two molecule circuit comprises two single molecule devices each comprising a molecule connected to a monatomic chain electrode connected in series.

8. A device as claimed in claim 1 comprising a high conductance near the Fermi Energy, E_{F}, with a transport channel mainly formed from the highest occupied molecule orbital (HOMO) and the lower unoccupied molecule orbital (LUMO) of the molecule.

9. A device as claimed in claim 8 comprising one transport channel in the electrodes wherein both the transmission and reflection matrices reduce to two complex numbers and wherein their absolute values squared correspond respectively to the transmission and reflection coefficient.

10. A device as claimed in claim 9 wherein the complex arguments of the transmission and reflection coefficients, the transmission phase et and the reflection phase or account for the phase shifts of an electron when either transmitted or reflected by the molecule.

11. A device as claimed in claim 10 wherein the transmission coefficient is modulated with gate voltage.

12. A device as claimed in claim 11, wherein application of a positive gate voltage causes a peak shift in the transmission coefficient shift to lower energies as the voltage increases, providing an increase in conductance at the Fermi Energy (E_{F}).

13. A device as claimed in claim 11 wherein modulation of transmission coefficient results in a change in the zero-bias conductance.

14. A device as claimed in claim 10, wherein the transmission co-efficient is an oscillating function of the energy of the incident electron.

15. A device as claimed in claim 10 wherein for electrodes with only one scattering channel the transmission coefficient of the device follows T₂=|T₁/(1−R₁ exp(2iθᵣ+2ika₀N))|², where T₁ and R₁ are the transmission and reflection coefficients of the single-molecule device and N denotes the number of unit cells in the interconnect.

16. A device as claimed in claim 10 wherein the transmission co-efficient oscillations of the of this phase-coherent system are determined by the exponent with the period mainly given by the band energy and the length of the interconnect:
$$Δ E = Δ k ( Δ E / Δ k ) • \frac{π}{( N + {N}_{0} ) {a}_{0}} \frac{\partial E}{\partial k}$$
assuming a linear relation between θᵣ and the wave vector θᵣ=ka₀N₀+C.

17. A device as claimed in claim 10 wherein the transmission and reflection phases θₜ and θᵣ show an approximately linear behavior with the wave vector k of the channel.

18. A device as claimed in claim 1 wherein the current-voltage (I-V) curve of the two molecule device is controlled by gating the interconnect.

19. A device as claimed in claim 17 wherein a step-like current-voltage (I-V) curve is obtained as a result of an oscillatory transmission coefficient.

20. A device as claimed in claim 1 wherein the conductance oscillates as a function of interconnect length.

21. A computer implemented method of simulating a molecular quantum interference device comprising two molecules connected via a one-dimensional interconnect wherein the interconnect between the molecules is gated and the applied gate voltage is controllable to control the electron phase in the interconnect, for use in analysing performance and/or determining the critical parameters of the molecular quantum interference device, the method including determining transport, phase relations and phase coefficients for the device using a divide and conquer technique combined with a scattering (S) matrix formalism.

22. The method of claim 21 further comprising use of a fully self consistent algorithm.

23. A method as claimed in claim 21 wherein the device is divided into sections comprising single molecule devices and the S-matrices of each section are calculated and combined in writing the S-matrix of the entire device.

24. A method as claimed in claim 23 wherein the total S-matrix is used to evaluate the conductance using the Landauer-Buttiker formula
$$T = {\sum }_{α β} {\vert {t}_{α β} \vert}^{2} ( {v}_{α}^{out} / {v}_{β}^{in} ) ,$$
where t is the transmission matrix, v^{out} and vⁱⁿ are the velocities of transmitted and incident waves respectively, and the subscript runs over different channels.

25. A method as claimed in claim 24 wherein the device comprises one transport channel, and both the transmission and reflection matrices reduce to two complex numbers and wherein the absolute values squared correspond to transmission and reflection coefficients and wherein their complex arguments, the transmission phase and the reflection phase account for the phase shifts of an electron when either transmitted or reflected by a molecule.
